(19) United States
(12) Patent Application Publication
(10) Pub. No.: US 2024/0213032 A1
(43) Pub. Date: Jun. 27, 2024

(54) ETCHING METHOD AND PLASMA PROCESSING APPARATUS

(71) Applicant: Tokyo Electron Limited, Tokyo (JP)

(72) Inventors: Koki MUKAIYAMA, Miyagi (JP); Takuya SAWANO, Miyagi (JP)

(73) Assignee: Tokyo Electron Limited, Tokyo (JP)

(21) Appl. No.: 18/395,788

(22) Filed: Dec. 26, 2023

(30) Foreign Application Priority Data
Dec. 27, 2022 (JP) 2022-210014

(51) Int. Cl. H01L 21/311; C23C 16/04; C23C 16/08; H01J 37/32; H01L 21/033

(52) U.S. Cl. CPC H01L 21/31122; C23C 16/045; C23C 16/08; H01J 37/32724; H01J 37/32816; H01L 21/0332; H01L 21/31116; H01J 2237/3321; H01J 2237/3341; H01J 2237/3346

(57) ABSTRACT

An etching method includes (a) providing a substrate having an etching target film and a mask on the etching target film, on a substrate support within a chamber; (b) etching the etching target film to form a recess under a condition that a pressure within the chamber is controlled to a first pressure, and a temperature of the substrate support is controlled to a first temperature; and (c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

### CROSS-REFERENCE TO RELATED APPLICATION

This application is based on and claims priority from Japanese Patent Application No. 2022-210014, filed on Dec. 27, 2022, with the Japan Patent Office, the disclosure of which is incorporated herein in its entirety by reference.

### TECHNICAL FIELD

An embodiment of the present disclosure relates to an etching method and a plasma processing apparatus.

### BACKGROUND

Japanese Patent Laid-Open Publication No. 2016-021546 discloses a technique in which after plasma etching is performed up to the middle of a silicon-containing film, a carbon-containing film is formed on the silicon-containing film without plasma generation, so that etching is performed while suppressing bowing.

### SUMMARY

In one embodiment of the present disclosure, an etching method is provided. The etching method includes (a) providing a substrate having an etching target film and a mask on the etching target film, on a substrate support within a chamber: (b) etching the etching target film to form a recess under a condition that a pressure within the chamber is controlled to a first pressure, and a temperature of the substrate support is controlled to a first temperature: and (c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a plasma processing apparatus.

FIG. 2 is a view illustrating a configuration example of an inductively coupled plasma processing apparatus.

FIG. 3 is a view illustrating an example of bowing.

FIG. 4 is a flow chart illustrating the present method.

FIG. 5 is a view illustrating an example of the cross-sectional structure of a substrate W provided in the step ST1.

FIG. 6 is a view illustrating an example of the cross-sectional structure of the substrate W after the processing in the step ST2.

FIGS. 7A to 7C are views illustrating an example of a metal-containing film forming process in the step ST3.

FIG. 8 is a view illustrating an example of the cross-sectional structure of the substrate W after the processing in the step ST4.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, each embodiment of the present disclosure will be described.

In one embodiment, an etching method is provided. The etching method includes the steps of (a) providing a substrate having an etching target film and a mask on the etching target film, on a substrate support within a chamber, (b) etching the etching target film to form a recess under a condition that a pressure within the chamber is controlled to a first pressure, and a temperature of the substrate support is controlled to a first temperature, and (c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

In one embodiment, in the step (c), the metal-containing film is formed on the side wall on a bottom side of the recess.

In one embodiment, in the step (c), the metal-containing film is formed on a bottom of the recess and near the bottom.

In one embodiment, in the step (c), the metal-containing film is formed on the side wall at a position deeper than a position of half of a depth of the recess.

In one embodiment, during the step (c), the metal-containing film is gradually formed upwards from a bottom of the recess.

In one embodiment, when the step (b) is ended, an aspect ratio of the recess is 20 or more.

In one embodiment, a step (d) of further etching the recess is further included after the step (c).

In one embodiment, the step (c) and the step (d) are alternately repeated multiple times.

In one embodiment, a depth of the recess at the end of the step (b) is 30% or more of a depth of the recess at the end of etching.

In one embodiment, the processing gas further contains a reducing gas.

In one embodiment, the metal-containing gas contains at least one metal selected from the group consisting of tungsten, titanium, and molybdenum.

In one embodiment, the metal-containing gas further contains halogen.

In one embodiment, the second temperature is less than 0° C.

In one embodiment, the second pressure is 150 mTorr or more.

In one exemplary embodiment, the etching target film contains carbon, and the mask contains silicon or metal.

In one embodiment, in the step (b), the etching target film is etched by using plasma generated from a processing gas containing an oxygen-containing gas.

In one embodiment, the etching target film contains silicon, and the mask contains carbon or metal.

In one embodiment, in the step (b), the etching target film is etched by using plasma generated from a processing gas containing a fluorine-containing gas.

In one embodiment, an etching method is provided. The etching method includes the steps of (a) providing a substrate having a recess, on a substrate support within a chamber: and (b) forming a metal-containing film on a portion of a side wall of the recess by using plasma generated from a processing gas containing a metal-containing gas under a condition that a pressure within the chamber is controlled to 150 mTorr or more, and a temperature of the substrate support is controlled to be less than 0° C.

In one embodiment, provided is a plasma processing apparatus having a chamber and a controller. In the plasma processing apparatus, the controller executes (a) a control of providing a substrate having an etching target film and a mask on the etching target film, on a substrate support within the chamber, (b) a control of etching the etching target film to form a recess under a condition that a pressure within the chamber is controlled to a first pressure, and a temperature of the substrate support is controlled to a first temperature, and (c) a control of forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

Hereinafter, each embodiment of the present disclosure will be described in detail with reference to drawings. In the drawings, the same or similar elements are denoted by the same reference numerals, and redundant explanations thereof will be omitted. Unless otherwise specified, positional relationships such as up, down, left, and right will be described on the basis of positional relationships illustrated in the drawings. The dimensional ratios in the drawings do not indicate actual ratios, and the actual ratios are not limited to the illustrated ratios.

### <Configuration Example of Plasma Processing Apparatus>

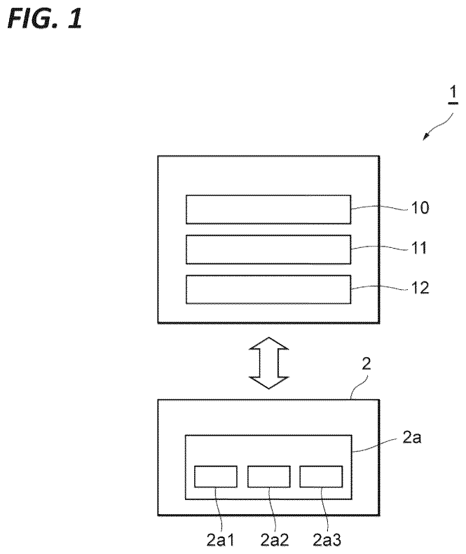

FIG. 1 is a view illustrating a configuration example of a plasma processing apparatus. In one embodiment, a plasma processing apparatus 1 is an example of a substrate processing apparatus. The plasma processing apparatus 1 includes a controller 2, a plasma processing chamber 10, a substrate support 11, and a plasma generator 12. The plasma processing chamber 10 has a plasma processing space. The plasma processing chamber 10 has at least one gas supply port for supplying at least one processing gas to the plasma processing space, and at least one gas outlet for discharging gas from the plasma processing space. The gas supply port is connected to a gas supply 20 to be described below, and the gas outlet is connected to an exhaust system 40 to be described below. The substrate support 11 is disposed within the plasma processing space, and has a substrate supporting surface for supporting a substrate.

The plasma generator 12 is configured to generate plasma from at least one processing gas supplied into the plasma processing space. The plasma formed in the plasma processing space may be, for example, capacitively coupled plasma (CCP), inductively coupled plasma (ICP), electron-cyclotron-resonance plasma (ECR plasma), helicon wave-excited plasma (HWP), or surface wave plasma (SWP). Various types of plasma generators, including an alternating current (AC) plasma generator and a direct current (DC) plasma generator, may be used. In one embodiment, the AC signal (AC power) used in the AC plasma generator has a frequency within a range of 100 kHz to 10 GHz. Therefore, AC signals include radio frequency (RF) signals and microwave signals. In one embodiment, the RF signal has a frequency within a range of 100 kHz to 150 MHz.

The controller 2 processes computer-executable instructions that cause the plasma processing apparatus 1 to execute various steps described in the present disclosure. The controller 2 may be configured to control each element of the plasma processing apparatus 1 so as to execute various steps described herein. In one embodiment, a part or all of the controller 2 may be configured as an external system of the plasma processing apparatus 1. The controller 2 may include a processor 2al, a storage 2a2, and a communication interface 2a3. The controller 2 is realized by, for example, a computer 2a. The processor 2al may be configured to read a program from the storage 2a2, and to execute the read program so as to perform various control operations. This program may be stored in the storage 2a2 in advance, or may be acquired via a medium if necessary. The acquired program is stored in the storage 2a2, and is read from the storage 2a2 by the processor 2al, and then is executed. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN).

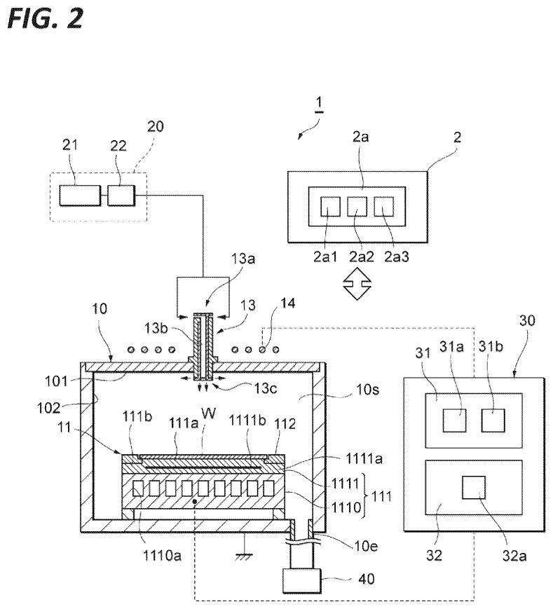

Hereinafter, descriptions will be made on a configuration example of an inductively coupled plasma processing apparatus as an example of the plasma processing apparatus 1. FIG. 2 is a view illustrating a configuration example of an inductively coupled plasma processing apparatus.

The inductively coupled plasma processing apparatus 1 includes the controller 2, the plasma processing chamber 10, the gas supply 20, a power supply 30, and the exhaust system 40. The plasma processing chamber 10 includes a dielectric window 101. The plasma processing apparatus 1 includes the substrate support 11, a gas introduction section, and an antenna 14. The substrate support 11 is disposed within the plasma processing chamber 10 (hereinafter, also referred to as a “chamber 10”). The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a main body 111 and a ring assembly 112. The main body 111 has a central region 111a for supporting a substrate W, and an annular region 111b for supporting the ring assembly 112. A wafer is an example of the substrate W. In plan view, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate supporting surface for supporting the substrate W, and the annular region 111b is also called a ring supporting surface for supporting the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a, and an electrostatic electrode 1111b disposed within the ceramic member 1111a.

The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power supply 31 and/or a DC power supply 32 to be described below may be disposed within the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or more annular members. In one embodiment, one or more annular members include one or more edge rings and at least one cover ring. The edge ring is made of a conductive material or an insulating material, and the cover ring is made of an insulating material.

The substrate support 11 may include a temperature control module configured to control at least one of the electrostatic chuck 1111, the ring assembly 112, and the substrate, to a target temperature. The temperature control module may include a heater, a heat transfer medium, and a flow path 1110a, or a combination thereof. A heat transfer fluid such as brine or gas flows through the flow path 1110a. In one embodiment, the flow path 1110a is formed within the base 1110, and one or more heaters are disposed within the ceramic member 1111a of the electrostatic chuck 1111. The substrate support 11 may include a heat transfer gas supply configured to supply a heat transfer gas to the gap between the back surface of the substrate W and the central region 111a.

The gas introduction section is configured to introduce at least one processing gas from the gas supply 20 into the plasma processing space 10s. In one embodiment, the gas introduction section includes a center gas injector (CGI) 13. The center gas injector 13 is disposed above the substrate support 11, and is attached to a central opening formed in the dielectric window 101. The center gas injector 13 includes at least one gas supply port 13a, at least one gas flow path 13b, and at least one gas introduction port 13c. The processing gas supplied to the gas supply port 13a is introduced into the plasma processing space 10s from the gas introduction port 13c through the gas flow path 13b. In addition to or instead of the center gas injector 13, the gas introduction section may include one or more side gas injectors (SGIs) attached to one or more openings formed in the side wall 102.

The gas supply 20 may include at least one gas source 21 and at least one flow controller 22. In one embodiment, the gas supply 20 is configured to supply at least one processing gas to the gas introduction section, from each corresponding gas source 21 through each corresponding flow controller 22. Each flow controller 22 may include, for example, a mass flow controller or a pressure control-type flow controller. Further, the gas supply 20 may include at least one flow modulation device that modulates the flow rate of at least one processing gas or makes a pulse of the flow rate.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. Accordingly, plasma is formed from at least one processing gas supplied to the plasma processing space 10s. Therefore, the RF power supply 31 may function as at least a portion of the plasma generator 12. When a bias RF signal is supplied to at least one bias electrode, a bias potential is generated in the substrate W, and ions in the formed plasma can be drawn into the substrate W.

In one embodiment, the RF power supply 31 includes a first RF generator 31a and a second RF generator 31b. The first RF generator 31a is coupled to the antenna 14 via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate source RF signals having different frequencies. One or more generated source RF signals are supplied to the antenna 14.

The second RF generator 31b is coupled to at least one bias electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate bias RF signals having different frequencies. One or more generated bias RF signals are supplied to at least one bias electrode. In various embodiments, at least one of the source RF signal and the bias RF signal may be pulsed.

The power supply 30 may include the DC power supply 32 coupled to the plasma processing chamber 10. The DC power supply 32 includes a bias DC generator 32a. In one embodiment, the bias DC generator 32a is connected to at least one bias electrode, and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a pulse waveform of a rectangle, a trapezoid, a triangle, or a combination thereof. In one embodiment, a waveform generator for generating a sequence of voltage pulses from DC signals is connected between the bias DC generator 32a and at least one bias electrode. Therefore, the bias DC generator 32a and the waveform generator constitute a voltage pulse generator. The voltage pulse may have a positive polarity or may have a negative polarity. The sequence of voltage pulses may include one or more positive voltage pulses and one or more negative voltage pulses within one period. The bias DC generator 32a may be provided in addition to the RF power supply 31, or may be provided instead of the second RF generator 31b.

The antenna 14 includes one or more coils. In one embodiment, the antenna 14 may include an outer coil and an inner coil which are coaxially arranged. In this case, the RF power supply 31 may be connected to both the outer coil and the inner coil, or may be connected to either one of the outer coil and the inner coil. In the former case, the same RF generator may be connected to both the outer coil and the inner coil, or separate RF generators may be separately connected to the outer coil and the inner coil.

The exhaust system 40 may be connected to, for example, a gas outlet 10e provided at the bottom of the plasma processing chamber 10. The exhaust system 40 may include a pressure regulation valve and a vacuum pump. By the pressure regulation valve, the pressure within the plasma processing space 10s is adjusted. The vacuum pump may include a turbomolecular pump, a dry pump, or a combination thereof.

### <Example of Bowing>

Bowing is known as one of shape abnormalities in plasma etching. The bowing is a phenomenon in which the opening width of a portion of the side wall of a recess formed by etching is larger than the opening width of the top of the recess. The portion where bowing is occurring has, for example, a barrel-like shape in the cross-sectional view. It is thought that bowing may occur when a portion of the side wall of the recess is scraped by ions, etc. rebounding from, for example, a mask.

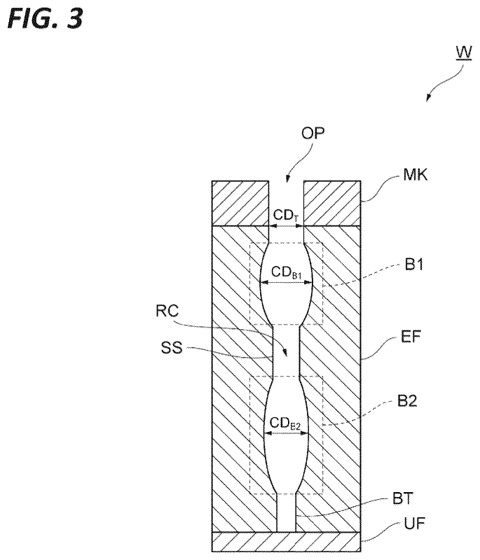

FIG. 3 is a view illustrating an example of bowing. FIG. 3 is an example of a cross-sectional structure when an etching target film EF of a substrate W is plasma-etched through a mask MK having an opening OP until the bottom of a recess RC reaches an underlayer film UF.

In the example illustrated in FIG. 3, a first bowing B1 having an opening size CD_{B1}(>opening size CDT) occurs on the upper side (the low to medium aspect region) of the recess RC. Further, a second bowing B2 having an opening size CD_{B2}(>opening size CDT) occurs on the bottom side (the high aspect region) of the recess. The first bowing B1 may be called a top bowing, and the second bowing B2 may be called a middle bowing or a second bowing in some cases. The second bowing B2 occurs in the high aspect region on the bottom side of the recess RC, and it has been conventionally difficult to suppress such bowing.

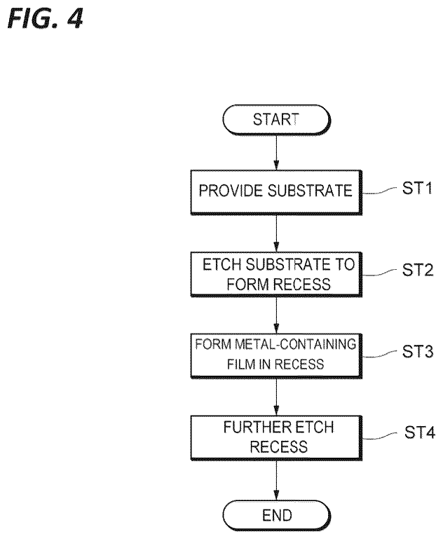

An etching method according to one embodiment of the present disclosure can suppress such bowing occurring in the high aspect region. Hereinafter, descriptions will be made with reference to FIGS. 4 to 8.

### <Example of Etching Method>

FIG. 4 is a flow chart illustrating an example of an etching method according to one embodiment (hereinafter, also referred to as “the present method”). As illustrated in FIG. 4, the present method includes a step ST1 of providing a substrate, a step ST2 of etching the substrate to form a recess, a step ST3 of forming a metal-containing film in the recess, and a step ST4 of further etching the recess. The processing in each step may be executed in the above-described plasma processing apparatus 1. Hereinafter, descriptions will be made on, as an example, a case where the controller 2 controls each part of the inductively coupled plasma processing apparatus 1 (see FIG. 2) so that the present method is executed on a substrate W.

### (Step ST1: Provision of Substrate)

In step ST1, the substrate W is provided into the plasma processing space 10s of the plasma processing apparatus 1. The substrate W is carried into the chamber 10 by a transfer arm, and is placed on the central region 111a of the substrate support 11. The substrate W is attracted and held on the substrate support 11 by the electrostatic chuck 1111.

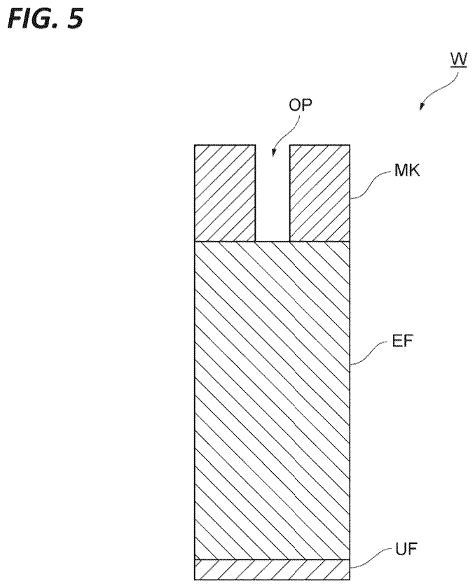

FIG. 5 is a view illustrating an example of the cross-sectional structure of the substrate W provided in the step ST1. The substrate W has an etching target film EF and a mask MK. The substrate W may further include an underlayer film UF. The substrate W may be used for manufacturing semiconductor devices. The semiconductor devices include, for example, semiconductor memory devices such as a DRAM and a 3D-NAND flash memory.

In one embodiment, the underlayer film UF is a silicon wafer, or an organic film, a dielectric film, a metal film, a semiconductor film, or a stacked film of these, which is formed on the silicon wafer. In one embodiment, the underlayer film UF includes at least one selected from the group consisting of a silicon-containing film, a carbon-containing film, and a metal-containing film.

The etching target film EF is a film to be etched in the present method. The etching target film EF may be composed of one film, or may be composed of films which are stacked.

In one embodiment, the etching target film EF is a film that contains carbon or silicon. In one embodiment, the etching target film EF is a silicon-containing film. As an example, the silicon-containing film is a silicon oxide film, a silicon nitride film, a silicon carbonitride film, a polycrystalline silicon film, or a stacked film including two or more of these films. For example, the silicon-containing film may be configured by alternately stacking a silicon oxide film and a silicon nitride film. For example, the silicon-containing film may be configured by alternately stacking a silicon oxide film and a polycrystalline silicon film. For example, the silicon-containing film may be a stacked film including a silicon nitride film, a silicon oxide film, and a polycrystalline silicon film.

In one embodiment, the etching target film EF is a carbon-containing film. As an example, the carbon-containing film is an amorphous carbon (ACL) film, a spin-on carbon (SOC) film, or a photoresist film. The amorphous carbon (ACL) film may be doped with an element such as boron, and may be, for example, a boron-containing amorphous carbon film (B-doped ACL), an arsenic-containing amorphous carbon film (As-doped ACL), a tungsten-containing amorphous carbon film (W-doped ACL), or a xenon-containing amorphous carbon film (Xe-doped ACL).

In one embodiment, the etching target film EF may include a metal-containing film. As an example, the metal-containing film may be a film containing at least one selected from the group consisting of tungsten, titanium, and molybdenum.

The mask MK may have a pattern to be transferred to the etching target film EF by etching. The mask MK may be a single-layer mask composed of one layer, or may be a multi-layer mask composed of two or more layers. As illustrated in FIG. 5, the mask MK defines at least one opening OP on the etching target film EF. The opening OP is a space above the etching target film EF, and is surrounded by the side wall of the mask MK. That is, the top surface of the etching target film EF has a region covered by the mask MK, and a region exposed at the bottom of the opening OP.

The opening OP may have any shape in plan view of the substrate W, that is, in a case where the substrate W is viewed in a direction from top to bottom in FIG. 5. The above shape may be, for example, a circle, an ellipse, a rectangle, a line, or a combination of one or more types of these shapes. The mask MK may have a plurality of side walls, and the plurality of side walls may define a plurality of openings OP. The openings OP may have linear shapes, respectively, and may form line and space patterns lined up at regular intervals. The openings OP may have hole shapes, respectively, and may form array patterns.

The mask MK may be made of a material whose etching rate with respect to plasma generated in the step ST2 or the step ST4 is lower than that of the etching target film EF. That is, the mask MK may be appropriately selected depending on the material of the etching target film EF.

For example, when the etching target film EF is a silicon-containing film, the mask MK may be a carbon-containing mask or a metal-containing mask. The carbon-containing mask may be an amorphous carbon film, a photoresist film, or a spin-on carbon (SOC) film. In an example, the mask MK is an amorphous carbon film. The metal-containing mask may be a film containing at least one selected from the group consisting of tungsten, titanium, and molybdenum. In an example, the metal-containing mask is a tungsten silicide film.

For example, when the etching target film EF is a carbon-containing film, the mask MK may be a silicon-containing mask or a metal-containing mask. The silicon-containing mask may be a silicon oxynitride film, a silicon oxide film, or a silicon nitride film. The metal-containing mask may be a film containing at least one selected from the group consisting of tungsten, titanium, and molybdenum. In an example, the metal-containing mask is a tungsten silicide film.

For example, when the etching target film EF is a metal-containing film, the mask MK may be a silicon-containing mask such as a silicon oxide film.

Each film (the underlayer film UF, the etching target film EF, or the mask MK) constituting the substrate W may be formed by, for example, a CVD method, an ALD method, or a spin coating method. The opening OP of the mask MK may be formed by etching the mask MK, or may be formed through lithography. Each film may be a flat film, or may be a film having unevenness. The substrate W may further include another film under the underlayer film UF. In this case, a recess having a shape corresponding to the opening OP may be formed in the etching target film EF and the underlayer film UF, and then may be used as a mask for etching another film mentioned above.

At least a portion of the process of forming each film of the substrate W may be performed within a space of the chamber 10. As an example, the step of forming the opening OP by etching the mask MK may be executed in the chamber 10. That is, the etching for the opening OP and the etching target film EF in the step ST2 to be described below may be continuously performed within the same chamber. Further, in providing the substrate W, after all of the films of the substrate W are formed in a device or a chamber outside the plasma processing apparatus 1, the substrate W may be carried into the plasma processing space 10s of the plasma processing apparatus 1, and then disposed on the central region 111a of the substrate support 11.

In one embodiment, after the substrate W is provided to the central region 111a of the substrate support 11, the substrate support 11 is controlled to a first temperature by a temperature control module. In an example, controlling the temperature of the substrate support 11 to the first temperature includes setting the temperature of the heat transfer fluid flowing through the flow path 1110a or the heater temperature to the first temperature or to a temperature different from the first temperature. The timing at which the heat transfer fluid starts to flow through the flow path 1110a may be prior to, after, or simultaneously with the placement of the substrate W on the substrate support 11. The temperature of the substrate support 11 may be controlled to the first temperature prior to the step ST1. That is, after the temperature of the substrate support 11 is controlled to the first temperature, the substrate W may be provided to the substrate support 11.

The first temperature may be appropriately set depending on the etching target film EF or the type of the processing gas (a first processing gas) to be used in the step ST2. In one embodiment, the first temperature is less than 0° C. In an example, the first temperature is −10° C. or less, −20° C. or less, −30° C. or less, −40° C. or less, −50° C. or less, −60° C. or less, or −70° C. or less.

In one embodiment, instead of the substrate support 11, the substrate W may be controlled to the first temperature. Controlling the temperature of the substrate W to the first temperature includes setting the temperature of the heat transfer fluid flowing through the flow path 1110a of the substrate support 11, and/or the heater temperature to the first temperature or to a temperature different from the first temperature.

### (Step ST2: Formation of Recess)

In the step ST2, the etching target film EF of the substrate W is etched to form a recess.

First, the first processing gas is supplied into the plasma processing space 10s from the gas supply 20. The first processing gas may be appropriately selected such that the etching target film EF is etched with a sufficient selectivity with respect to the mask MK. For example, when the etching target film EF is a silicon-containing film, the first processing gas may contain a fluorine-containing gas. The fluorine-containing gas is, for example, a hydrogen fluoride gas (HF gas), a fluorocarbon gas, or a hydrofluorocarbon gas. For example, when the etching target film is a carbon-containing film, the first processing gas may contain an oxygen-containing gas. The oxygen-containing gas is, for example, O₂ gas, CO gas, CO₂ gas, or COS gas. For example, when the etching target film is a metal-containing film, the first processing gas may contain a halogen-containing gas (e.g., BCl₃ gas, SiCl₄ gas, and NF₃ gas) and an oxygen-containing gas (e.g., O₂ gas, CO gas, and CO₂ gas). The halogen-containing gas and the oxygen-containing gas may be supplied to the plasma processing space 10s simultaneously or alternately.

During the processing in the step ST2, the gas contained in the first processing gas or the flow rate (partial pressure) of the gas may or may not be changed. For example, when the etching target film EF is composed of a stacked film including different types of films, the composition of the processing gas or the flow rate (partial pressure) of each gas may be changed as the etching progresses (that is, depending on the type of a film to be etched).

Next, a source RF signal is supplied to the antenna 14. Accordingly, a high frequency electric field is generated within the plasma processing space 10s, plasma is generated from the first processing gas, and the etching target film EF is etched. A bias signal may be supplied to the lower electrode of the substrate support 11. In this case, a bias potential is generated between the plasma and the substrate W, and active species within the plasma such as ions and radicals are attracted to the substrate W so that the etching of the etching target film EF may be promoted. The bias signal may be a bias RF signal supplied from the second RF generator 31b. The bias signal may be a bias DC signal supplied from the DC generator 32a.

Both the source RF signal and the bias signal may be continuous waves or pulsed waves, or one may be a continuous wave and the other may be a pulsed wave. When both the source RF signal and the bias signal are pulsed waves, the periods of both pulsed waves may or may not be synchronized. The duty ratio of the pulsed waves of the source RF signal and/or the bias signal may be appropriately set, and may be, for example, 1 to 80%, or may be 5 to 50%. When the bias DC signal is used as the bias signal, the pulsed wave may have a waveform of a rectangle, a trapezoid, a triangle, or a combination thereof. The polarity of the bias DC signal may be negative or positive as long as the potential of the substrate W is set so as to provide a potential difference between the plasma and the substrate and to draw ions.

In the step ST2, supply and stop of at least one of the source RF signal and the bias signal may be alternately repeated. For example, supply and stop of the bias signal may be alternately repeated while the source RF signal is continuously supplied. For example, the bias signal may be continuously supplied while supply and stop of the source RF signal are alternately repeated. For example, supply and stop of both the source RF signal and the bias signal may be alternately repeated.

During the processing in the step ST2, the temperature of the substrate support 11 is controlled to the first temperature set in the step ST1. In one embodiment, instead of the temperature of the substrate support 11, the temperature of the substrate W may be controlled to the first temperature.

During the processing in the step ST2, the pressure within the plasma processing space 10s is controlled to a first pressure. In one embodiment, the first pressure is less than 150 mTorr (20 Pa). In an example, the first pressure may be 100 mTorr (13.3 Pa) or less, or 50 mTorr (6.7 Pa) or less.

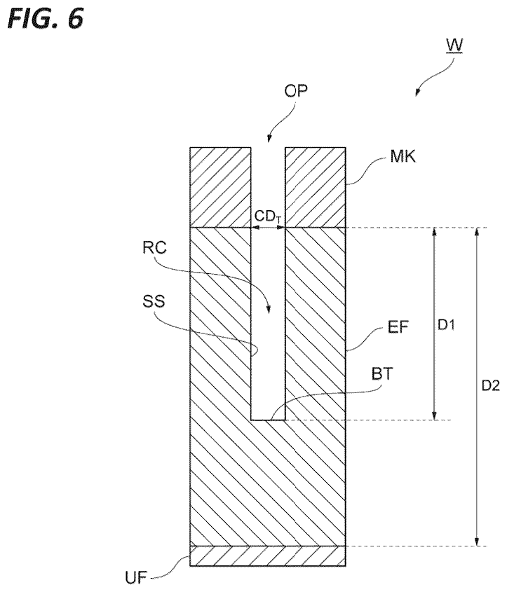

FIG. 6 is a view illustrating an example of the cross-sectional structure of the substrate W after the processing in the step ST2. As illustrated in FIG. 6, through the etching in the step ST2, a portion of the etching target film EF exposed through the opening OP is etched in the depth direction (a direction from top to bottom in FIG. 6). Accordingly, a recess RC is formed in the etching target film EF.

Through the processing in the step ST2, a portion of the etching target film EF not covered by the mask MK (a portion exposed through the opening OP) is etched and the recess RC is formed. The recess RC is a space defined by a side wall SS and a bottom BT.

In one embodiment, the aspect ratio of the recess RC after the processing in the step ST2 (in the example illustrated in FIG. 6, the ratio of the opening size CDT at the top of the recess to the depth D1 of the recess RC) may be 20 or more, 40 or more, 50 or more, or 60 or more. In an example, after the processing in the step ST2, the aspect ratio of the recess RC is 40 or more.

In one embodiment, the depth of the recess RC after the processing in the step ST2 (in the example illustrated in FIG. 6, the depth D1 of the recess RC) may be 30% or more, 50% or more, 60% or more, 70% or more, 80% or more, or 90% or more of a final etching depth (in the example illustrated in FIG. 6, the depth D2 to the underlayer film UF).

### (Step ST3: Formation of Metal-Containing Film)

In the step ST3, a metal-containing film is formed in the recess RC of the etching target film EF. First, a second processing gas that contains a metal-containing gas is supplied into the plasma processing space 10s from the gas supply 20.

In one embodiment, the metal-containing gas contains at least one among metals selected from the group consisting of tungsten, titanium, and molybdenum. In one embodiment, the metal-containing gas may further contain halogen.

In one embodiment, the metal-containing gas may be a gas containing tungsten and halogen, and is, for example, WFₓCl_{y} gas (x and y are each an integer from 0 to 6, and the sum of x and y is 2 to 6). Specifically, the tungsten-containing gas may be a gas containing tungsten and fluorine, such as tungsten difluoride (WF₂) gas, tungsten tetrafluoride (WF₄) gas, tungsten pentafluoride (WF₅) gas, and tungsten hexafluoride (WF₆) gas, or a gas containing tungsten and chlorine, such as tungsten dichloride (WCl₂) gas, tungsten tetrachloride (WCl₄) gas, tungsten pentachloride (WCl₅) gas, and tungsten hexachloride (WCl₆) gas. Among these, the gas may be at least one of WF₆ gas and WCl₆ gas. In one embodiment, the metal-containing gas may be a gas containing molybdenum or titanium, and halogen, and may be, for example, MoF₄ gas, MoCl₆ gas, TiCl₄ gas, etc.

In one embodiment, the flow rate of the metal-containing gas in the second processing gas may be 50 vol % or less, 40 vol % or less, 30 vol % or less, 20 vol % or less, 10 vol % or less, 5 vol % or less, or 3 vol % or less of the total flow rate of the second processing gas (when the second processing gas contains an inert gas, the flow rate of the inert gas is excluded).

In one embodiment, the metal-containing gas may be a low vapor pressure gas. The low vapor pressure gas is, for example, a gas that reaches a vapor pressure at a temperature equal to or higher than the temperature indicated by the temperature-vapor pressure curve of C₄F₈.

In one embodiment, the second processing gas may further include a reducing gas. The reducing gas may include, for example, at least one selected from the group consisting of H₂ gas, SiH₄ gas, CH₄ gas, C₂H₂ gas, C₂H₄ gas, C₃H₆ gas, CO gas, CO₂ gas, and COS gas.

In one embodiment, the second processing gas may further include an inert gas. The inert gas may be, for example, a rare gas such as Ar gas, He gas, and Kr gas, or a nitrogen gas.

Next, a source RF signal is supplied to the antenna 14. Accordingly, a high frequency electric field is generated within the plasma processing space 10s, and plasma is generated from the second processing gas. Therefore, the metal-containing film is formed in the recess RC of the etching target film EF. Here, no bias signal may be supplied to the lower electrode of the substrate support 11. A bias signal may be supplied to the lower electrode of the substrate support 11. In that case, the level of this bias signal (the power level or the voltage level) may be lower than the level of the bias signal supplied to the substrate support 11 in the step ST2 or the step ST4.

During the processing in the step ST3, the temperature of the substrate support 11 is controlled to a second temperature. The second temperature is a temperature equal to or lower than the first temperature. In one embodiment, the second temperature is less than 0° C. In an example, the second temperature is −10° C. or less, −20° C. or less, −30° C. or less, −40° C. or less, −50° C. or less, −60° C. or less, or −70° C. or less. In one embodiment, instead of the temperature of the substrate support 11, the temperature of the substrate W may be controlled to the second temperature.

During the processing in the step ST3, the pressure within the plasma processing space 10s is controlled to a second pressure. The second pressure is a pressure higher than the first pressure. In one embodiment, the second pressure is 150 mTorr (20 Pa) or more. In an example, the second pressure is 200 m Torr (26.7 Pa) or more, 300 mTorr (40 Pa) or more, or 400 mTorr (53.3 Pa) or more.

In the step ST3, a metal-containing film MD is formed in the recess RC by plasma generated from the second processing gas that contains the metal-containing gas. In one embodiment, the metal-containing film MD is formed on the side wall SS on the bottom side of the recess RC. In one embodiment, the metal-containing film may be continuously formed from the side wall SS on the bottom side to a portion of the side wall SS on the top side of the recess RC, or may not be formed on the side wall SS on the top side of the recess RC. The “bottom side” may be a position (deep) below half of the depth D1 of the recess RC (see FIG. 6), and the “top side” may be a position (shallow) above half of the depth D1 of the recess RC. In one embodiment, the metal-containing film MD may be formed on the bottom BT of the recess RC. The metal-containing film MD may be continuously formed over the bottom BT of the recess RC and the side wall SS near the bottom BT. The metal-containing film MD may provide protection for the side wall SS on which the metal-containing film MD is formed, when the recess RC is further etched in the step ST4.

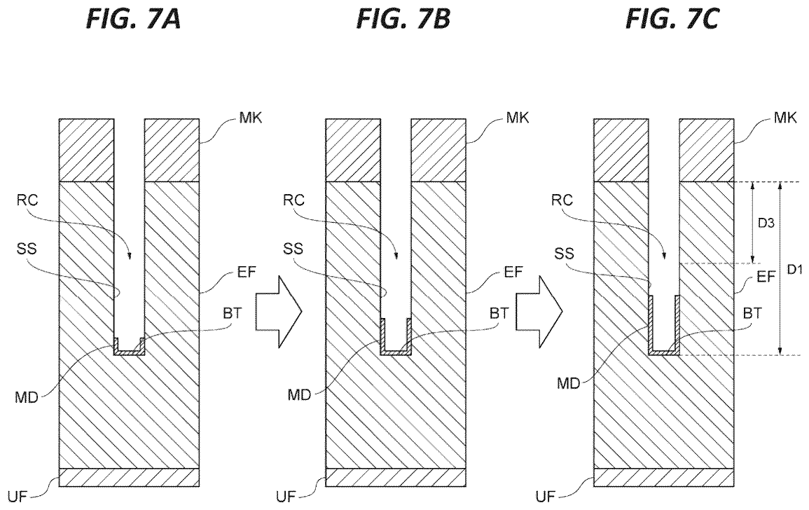

FIGS. 7A to 7C are views illustrating an example of a metal-containing film forming process in the step ST3. FIGS. 7A to 7C illustrate examples of the cross-sectional state of the substrate W at the initial, middle, and final stages of the step ST3, respectively. As sequentially illustrated in FIGS. 7A to C, the metal-containing film MD may be formed on the side wall SS in a bottom-up manner upwards from the bottom BT of the recess RC. At the end of the step ST3 (FIG. 7C), the metal-containing film MD is formed over the bottom BT and the side wall SS (deep) positioned below the depth D3. In one embodiment, the depth D3 may be 50% (half) of the depth D1 of the recess RC, or may be 60%, 70%, 80%, or 90%.

### (Step ST4: Etching of Recess)

In the step ST4, the recess RC of the etching target film EF is further etched. The step ST4 may be performed in the same manner as the above-described etching in the step ST2. In the step ST4, at least a portion of etching conditions (e.g., the type of a processing gas, the pressure within the chamber 10, the temperature of the substrate support 11, the level of a source RF signal, the presence/absence or level of a bias signal) may be changed from the step ST2.

In the etching of the step ST4, the metal-containing film MD can provide protection for the side wall SS on which the metal-containing film MD is formed. That is, it is possible to suppress the side wall SS of the above portion from expanding in the width direction, i.e., occurrence of bowing.

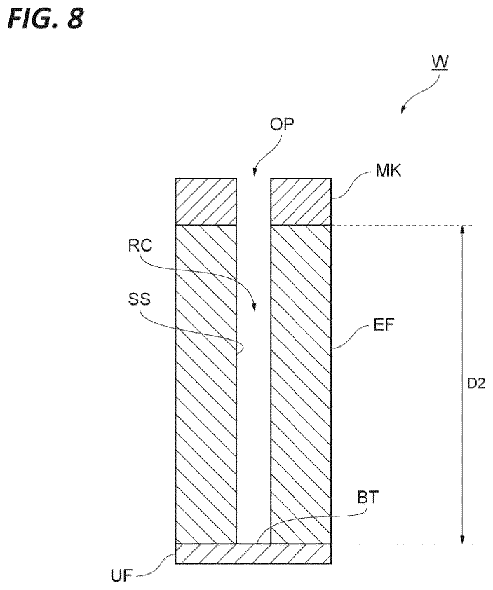

FIG. 8 is a view illustrating an example of the cross-sectional structure of the substrate W after the processing in the step ST4. As illustrated in FIG. 8, through the processing of the step ST4, the recess RC is further etched to the depth D2 in the depth direction, and the bottom BT has reached the underlayer film UF. In the example illustrated in FIG. 8, the metal-containing film MD is removed as etching progresses. Meanwhile, due to the protection effect of the metal-containing film MD, bowing is suppressed from occurring on the side wall SS of the recess RC, including the high aspect region.

According to the present method, in the step ST3, the metal-containing film is formed on the side wall SS on at least the bottom side of the recess RC. Accordingly, it is possible to suppress bowing from occurring on the bottom side (the high aspect region) of the recess RC during the etching of the recess in the step ST4. That is, the occurrence of the second bowing (middle bowing, second bowing) illustrated in FIG. 3 can also be suppressed.

### <Modification>

Various modifications of the present method may be made without departing from the scope and spirit of the present disclosure. In one embodiment, the processing according to the present method may not be executed in the same chamber 10. For example, the step ST2 and the step ST3 may be executed in different plasma processing chambers. Further, for example, the step ST3 and the step ST4 may be executed in different plasma processing chambers.

In one embodiment, the step ST3 and the step ST4 may be repeated. That is, the step ST3 and the step ST4 may be set as one cycle. Then, the cycle may be repeated multiple times, so that formation of the metal-containing film, and etching of the recess may be alternately repeated.

### EXAMPLES

Next, Examples of the present method will be described. The present disclosure is not limited by the following Examples at all.

### Example 1

In accordance with the flow chart illustrated in FIG. 4, a substrate having the same structure as the substrate W illustrated in FIG. 5 was etched by using the plasma processing apparatus 1 illustrated in FIG. 2. A mask MK was a silicon oxynitride film, and an etching target film EF was an amorphous carbon film. The opening OP of the mask MK had a hole shape, and the opening diameter was 80 nm.

In Example 1, in the step ST2, the first processing gas contained O₂ gas and COS gas. In the step ST2, in addition to a source RF signal, a bias RF signal was supplied. In the step ST2, the pressure within the chamber 10 was controlled to 30 mTorr, and the temperature of the substrate support 11 was controlled to −60° C. The step ST2 was executed for 240 sec.

In Example 1, in the step ST3, the second processing gas contained WF₆ gas (a metal-containing gas), H₂ gas (a reducing gas), and Ar gas (an inert gas). In the step ST3, only a source RF signal was supplied, and a bias signal was not supplied. In the step ST3, the pressure within the chamber 10 was controlled to 200 mTorr, and the temperature of the substrate support 11 was controlled to −60° C. The step ST3 was executed for 60 sec.

In Example 1, the step ST4 was executed under the same conditions as the step ST2. The step ST4 was executed for 180 sec.

Through the processing in Example 1, a recess RC of approximately 3.5 μm was formed in the etching target film EF. As a result of observation on the cross section of the recess RC, no bowing occurrence was observed even in a high aspect region with a depth of 2 μm or less.

### Experiments

Next, experiments were performed to verity the time dependence, the temperature dependence, and the pressure dependence in relation to the formation of a metal-containing film MD in the step ST2. The present disclosure is not limited by the following experiments at all.

(Time dependence)

The same substrates as in Example 1 were subjected to the step ST2, for 10 sec, 20 sec, and 60 sec, respectively, under the same conditions as in Example 1, and then the film formation status of the metal-containing film MD was observed. In the substrate on which the step ST2 was executed for 10 sec, the metal-containing film MD was formed on the bottom of the recess and the side wall up to 53 nm above the bottom. In the substrate on which the step ST2 was executed for 20 sec, the metal-containing film MD was formed on the bottom of the recess and the side wall up to 64 nm above the bottom. In the substrate on which the step ST2 was executed for 60 sec, the metal-containing film MD was formed on the bottom of the recess and the side wall up to 249 nm above the bottom. That is, as the processing time of the step ST2 increased, the metal-containing film MD was formed to the upper portion from the bottom.

### (Temperature Dependence)

On the same substrates as in Example 1, the step ST2 was executed for 60 sec under the same conditions as in Example 1 except that the temperature of the substrate support 11 was changed, and then the film formation status of the metal-containing film MD was observed. In the substrate for which the temperature of the substrate support 11 was set as −60° C., the metal-containing film MD was formed on the bottom and the side wall near the bottom. On the other hand, in the substrate for which the temperature of the substrate support 11 was set as 0° C., the formation of the metal-containing film MD was not confirmed.

### (Pressure Dependence)

On the same substrates as in Example 1, the step ST2 was executed for 60 sec under the same conditions as in Example 1 except that the pressure within the chamber 10 was changed, and then the film formation status of the metal-containing film MD was observed. In all of the substrates for which the pressure within the chamber 10 was set as 150 mTorr, 200 mTorr, 300 mTorr, and 400 mTorr, the metal-containing film MD was formed on the bottom and the side wall near the bottom. On the other hand, in the substrate for which the pressure within the chamber 10 was set as 100 mTorr, the formation of the metal-containing film MD was not confirmed.

The embodiment of the present disclosure further includes the following aspects.

### APPENDIX 1

An etching method including:
(a) providing a substrate having an etching target film and a mask on the etching target film, on a substrate support within a chamber;
(b) etching the etching target film to form a recess under a condition that a pressure within the chamber is controlled to a first pressure, and a temperature of the substrate support is controlled to a first temperature; and
(c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

### APPENDIX 2

The etching method described in Appendix 1, in which in (c), the metal-containing film is formed on the side wall on a bottom side of the recess.

### APPENDIX 3

The etching method described in Appendix 1 or 2, in which in (c), the metal-containing film is formed on a bottom of the recess and near the bottom.

### APPENDIX 4

The etching method described in any one of Appendixes 1 to 3, in which in (c), the metal-containing film is formed on the side wall at a position deeper than a position of half of a depth of the recess.

### APPENDIX 5

The etching method described in any one of Appendixes 1 to 4, in which during (c), the metal-containing film is gradually formed upwards from a bottom of the recess.

### APPENDIX 6

The etching method described in any one of Appendixes 1 to 5, in which an aspect ratio of the recess is 20 or more at an end of (b).

### APPENDIX 7

The etching method described in any one of Appendixes 1 to 6, further including: (d) further etching the recess after (c).

### APPENDIX 8

The etching method described in Appendix 7, in which (c) and (d) are alternately repeated a plurality of times.

### APPENDIX 9

The etching method described in Appendix 7 or 8, in which a depth of the recess at an end of (b) the etching of the etching target film is 30% or more of a depth of the recess at an end of etching.

### APPENDIX 10

The etching method described in any one of Appendixes 1 to 9, in which the processing gas further contains a reducing gas.

### APPENDIX 11

The etching method described in any one of Appendixes 1 to 10, in which the metal-containing gas contains at least one metal selected from the group consisting of tungsten, titanium, and molybdenum.

### APPENDIX 12

The etching method described in Appendix 11, in which the metal-containing gas further contains halogen.

### APPENDIX 13

The etching method described in any one of Appendixes 1 to 12, in which the second temperature is less than 0° C.

### APPENDIX 14

The etching method described in any one of Appendixes 1 to 13, in which the second pressure is 150 mTorr or more.

### APPENDIX 15

The etching method described in any one of Appendixes 1 to 14, in which the etching target film contains carbon, and the mask contains silicon or metal.

### APPENDIX 16

The etching method described in Appendix 15, in which in (b), the etching target film is etched by using plasma generated from a processing gas containing an oxygen-containing gas.

### APPENDIX 17

The etching method described in any one of Appendixes 1 to 14, in which the etching target film contains silicon, and the mask contains carbon or metal.

### APPENDIX 18

The etching method described in Appendix 17, in which in (b), the etching target film is etched by using plasma generated from a processing gas containing a fluorine-containing gas.

### APPENDIX 19

An etching method including:
(a) providing a substrate having a recess, on a substrate support within a chamber; and
(b) forming a metal-containing film on a portion of a side wall of the recess by using plasma generated from a processing gas containing a metal-containing gas, under a condition that a pressure within the chamber is controlled to 150 mTorr or more, and a temperature of the substrate support is controlled to be less than 0° C.

### APPENDIX 20

A plasma processing apparatus including a chamber and a controller,
in which the controller controls a process including:
(a) providing a substrate having an etching target film and a mask on the etching target film, on a substrate support within the chamber,
(b) etching the etching target film to form a recess under a condition that a pressure within the chamber is controlled to a first pressure, and a temperature of the substrate support is controlled to a first temperature, and
(c) forming a metal-containing film on a part of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

### APPENDIX 21

A plasma processing apparatus having a chamber and a controller, in which the controller controls a process including:
(a) providing a substrate having a recess, on a substrate support within the chamber, and
(b) forming a metal-containing film on a portion of a side wall of the recess by using plasma generated from a processing gas containing a metal-containing gas under a condition that a pressure within the chamber is controlled to 150 mTorr or more, and a temperature of the substrate support is controlled to be less than 0° C.

### APPENDIX 22

A device manufacturing method executed in a plasma processing apparatus having a chamber and a controller, the device manufacturing method including:
(a) providing a substrate having an etching target film and a mask on the etching target film, on a substrate support within a chamber,
(b) etching the etching target film to form a recess under a condition that a pressure within the chamber is controlled to a first pressure, and a temperature of the substrate support is controlled to a first temperature, and
(c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

### APPENDIX 23

A device manufacturing method executed in a plasma processing apparatus having a chamber and a controller, the device manufacturing method including:
(a) providing a substrate having a recess, on a substrate support within the chamber, and
(b) forming a metal-containing film on a portion of a side wall of the recess by using plasma generated from a processing gas containing a metal-containing gas under a condition that a pressure within the chamber is controlled to 150 mTorr or more, and a temperature of the substrate support is controlled to be less than 0° C.

### APPENDIX 24

A program that causes a computer in a plasma processing apparatus having a chamber and a controller, to control a process including:
(a) providing a substrate having an etching target film and a mask on the etching target film, on a substrate support within the chamber,
(b) etching the etching target film to form a recess, under a condition that a pressure within the chamber is controlled to a first pressure, and a temperature of the substrate support is controlled to a first temperature, and
(c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

### APPENDIX 25

A program that causes a computer in a plasma processing apparatus having a chamber and a controller, to control a process including:
(a) providing a substrate having a recess, on a substrate support within the chamber, and
(b) forming a metal-containing film on a portion of a side wall of the recess by using plasma generated from a processing gas containing a metal-containing gas, under a condition that a pressure within the chamber is controlled to 150 mTorr or more, and a temperature of the substrate support is controlled to be less than 0° C.

### APPENDIX 26

A storage medium storing the program described in Appendix 24 or 25.

According to one embodiment of the present disclosure, a technique of suppressing bowing can be provided.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a substrate having an etching target film and a mask on the etching target film, on a substrate support within a chamber;
(b) etching the etching target film to form a recess under a condition that a pressure within the chamber is controlled to a first pressure, and a temperature of the substrate support is controlled to a first temperature; and
(c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.

2. The etching method according to claim 1, wherein in (c), the metal-containing film is formed on the side wall on a bottom side of the recess.

3. The etching method according to claim 1, wherein in (c), the metal-containing film is formed on a bottom of the recess and near the bottom.

4. The etching method according to claim 1, wherein in (c), the metal-containing film is formed on the side wall at a position deeper than a position of half of a depth of the recess.

5. The etching method according to claim 1, wherein during (c), the metal-containing film is gradually formed upwards from a bottom of the recess.

6. The etching method according to claim 1, wherein an aspect ratio of the recess is 20 or more at an end of (b).

7. The etching method according to claim 1, further comprising:
(d) further etching the recess after (c).

8. The etching method according to claim 7, wherein (c) and (d) are alternately repeated a plurality of times.

9. The etching method according to claim 7, wherein a depth of the recess at an end of (b) the etching of the etching target film is 30% or more of a depth of the recess at an end of etching.

10. The etching method according to claim 1, wherein the processing gas further contains a reducing gas.

11. The etching method according to claim 1, wherein the metal-containing gas contains at least one metal selected from the group consisting of tungsten, titanium, and molybdenum.

12. The etching method according to claim 11, wherein the metal-containing gas further contains halogen.

13. The etching method according to claim 1, wherein the second temperature is less than 0° C.

14. The etching method according to claim 1, wherein the second pressure is 150 mTorr or more.

15. The etching method according to claim 1, wherein the etching target film contains carbon, and the mask contains silicon or metal.

16. The etching method according to claim 15, wherein in (b), the etching target film is etched by using plasma generated from a processing gas containing an oxygen-containing gas.

17. The etching method according to claim 1, wherein the etching target film contains silicon, and the mask contains carbon or metal.

18. The etching method according to claim 17, wherein in (b), the etching target film is etched by using plasma generated from a processing gas containing a fluorine-containing gas.

19. An etching method comprising:
(a) providing a substrate having a recess, on a substrate support within a chamber; and
(b) forming a metal-containing film on a portion of a side wall of the recess by using plasma generated from a processing gas containing a metal-containing gas, under a condition that a pressure within the chamber is controlled to 150 mTorr or more, and a temperature of the substrate support is controlled to be less than 0° C.

20. A plasma processing apparatus comprising:
a chamber having at least one gas inlet and at least one gas outlet;
a substrate support in the chamber; and
a controller configured to cause:
(a) placing a substrate having an etching target film and a mask on the etching target film, on the substrate support,
(b) etching the etching target film to form a recess under a condition that a pressure within the chamber is controlled to a first pressure, and a temperature of the substrate support is controlled to a first temperature, and
(c) forming a metal-containing film on a portion of a side wall of the recess by using plasma generated from a processing gas containing a metal-containing gas, under a condition that the pressure within the chamber is controlled to a second pressure higher than the first pressure, and the temperature of the substrate support is controlled to a second temperature equal to or less than the first temperature.
